(19) United States
(12) Patent Application Publication
(10) Pub. No.: US 2025/0258436 A1
(43) Pub. Date: Aug. 14, 2025

(54) EUV COLLECTOR FOR USE IN AN EUV PROJECTION EXPOSURE APPARATUS

(71) Applicant: Carl Zeiss SMT GmbH, Oberkochen (DE)

(72) Inventors: Dirk EHM, Beckingen (DE); Wolfgang MERKEL, Neu-Ulm (DE)

(21) Appl. No.: 18/437,409

(22) Filed: Feb. 9, 2024

(51) Int. Cl. G03F 7/00

(52) U.S. Cl. CPC G03F 7/70175; G03F 7/70141; G03F 7/702

(57) ABSTRACT

An EUV collector (24) serves for use in an EUV projection exposure apparatus for guiding EUV used light emanating from a source region of an EUV light source. The collector (24) has at least one reflection surface (30) that is curved to obtain a specified optical power. The collector (24) furthermore has at least one interchangeable reflection surface section (31ᵢ) and a holder (45) for holding the interchangeable reflection surface section (31ᵢ) in a collector recess (32) which is complementary to the interchangeable reflection surface section and is located in the EUV collector (24). The interchangeable reflection surface section (31ᵢ) is curved in accordance with the specified optical power. The outlay for testing collector materials and/or collector coating materials is reduced in the case of such an EUV collector.

### CROSS REFERENCE TO RELATED APPLICATIONS

This is a Continuation of International Application PCT/EP2022/071800 which has an international filing date Aug. 3, 2022, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2021 208 674.8 filed on Aug. 10, 2021.

### FIELD OF THE INVENTION

The invention relates to an extreme-ultraviolet (EUV) collector for use in an EUV projection exposure apparatus. Further, the invention relates to an interchange apparatus for exchanging an interchangeable reflection surface section held on such an EUV collector with a swap interchangeable reflection surface section. Furthermore, the invention relates to an illumination system having such a collector, an optical system having such an illumination system, a projection exposure apparatus having such an optical system, a method for producing a microstructured or nanostructured component and a microstructured or nanostructured component produced by this method.

### BACKGROUND

An EUV collector of the type set forth at the outset is known from DE 10 2019 200 698 A1, WO 2017/174 423 A1, US 2019/0 302 628 A1, US 2013/0 335 816 A1 and U.S. Pat. No. 7,084,412 B2. An EUV collector having interchangeable reflection surface sections is known from the presentation “High power LPP-EUV source with long collector mirror lifetime for high volume semiconductor manufacturing” by H. Mizoguchi, Gigaphoton, SEMICON JAPAN 2017.

### SUMMARY

It is an object of the present invention to develop an EUV collector of the type set forth at the outset that the outlay for testing collector materials and/or collector coating materials is reduced.

According to one aspect of the invention, this object is addressed with an EUV collector configured to guide EUV used light and having the following features:
at least one reflection surface that is curved to obtain a specified optical power,
a plurality of interchangeable reflection surface sections, and
a plurality of holders assigned to and configured to hold the interchangeable reflection surface sections in a collector recess which is configured complementary to the interchangeable reflection surface sections and is located in the EUV collector,
wherein the interchangeable reflection surface sections are curved in accordance with the specified optical power.

According to the invention, it was recognized that the use of an EUV collector having at least one interchangeable reflection surface section curved in accordance with a specified optical power of the reflection surface of the EUV collector leads to the option of also using the EUV collector for the production within an EUV projection exposure apparatus during a test operation. It is possible to test collector substrate materials and coatings for the collector reflection surface by using appropriate interchangeable reflection surface sections with substrates and/or coatings made of these materials. In this case, the substrates and/or the coatings of the interchangeable reflection surface sections can be designed exactly as required by the EUV collector for obtaining the corresponding optical power during the EUV production operation of the projection exposure apparatus. A very realistic test of the substrate materials and the coatings can be achieved in this way since production conditions may prevail during testing. It is possible to test highly reflective coatings and/or diffraction gratings and/or other diffractive structures, for example computer-generated holograms (CGH). The respective interchangeable reflection surface section can merge as seamlessly as possible into reflection surface surroundings around the interchangeable reflection surface section held in the collector recess. This can be achieved by appropriately precise shaping of the interchangeable reflection surface section and the collector recess, complementary thereto, of the EUV collector. The holder for the interchangeable reflection surface section can be a holder with a locking effect, for example a latching holder. The coatings to be tested can be multilayer coatings. In particular, the EUV collector facilitates a service-life test of certain materials and/or material combinations of a substrate or main body of the interchangeable reflection surface section and/or of a coating therefor. Corresponding service-life tests can be carried out with realistic conditions for a given vacuum and for an apparatus function of the projection exposure apparatus used for production, in particular with real specifications for an EUV light source and for a typical production operation duration.

The optical behavior of the interchangeable reflection surface section can be registered during operation of the projection exposure apparatus by way of an appropriate reflectivity measurement, or else by the determination of further parameters, for example a heating of said reflection surface section.

The holder may comprise orientation markings for ensuring correct positioning of the respective interchangeable reflection surface section. Such markings may be designed as optical markings or else as mechanically complementary markings, for example as tongue/groove fits. In this case, a tongue of the respective interchangeable reflection surface section can engage in a corresponding groove of the holder when positioned correctly.

In particular, influences of wavelengths not used for the projection exposure which emanate from a source region of an EUV light source of the projection exposure apparatus can then be realistically examined using the EUV collector. This especially applies to an EUV wavelength range between 80 nm and 120 nm that is regularly not used for the projection exposure.

It is also possible then to realistically examine the influences of plasma near the collector reflection surface, for example the influence of a hydrogen, nitrogen, oxygen and water partial pressure. The influence of debris, in particular of the target material or its ionized constituents from the EUV source, on the EUV collector can also be examined.

Further degradation influences that can be examined include an oxidation, a carbon growth, a contamination with inorganic components, an inclusion of foreign atoms or else a mechanical degradation by layers spalling or by delamination. It is also possible to examine the influence of a plasma intensity, the influence of an ion energy and the influence of an ion flow, which may arise in conjunction with the EUV generation, on the collector reflection surface.

Even the reflection surface of the EUV collector beyond the interchangeable reflection surface sections may have a coating that is reflective and, in particular, highly reflective for EUV light, in particular for EUV used light wavelengths.

A plurality of interchangeable reflection surface sections and assigned holders facilitates testing at various locations on the reflection surface of the EUV collector, which may for example have turned out to be critical during preceding operation. A test of different materials or material combinations and a test for example of different designs of coating layer structures and of diffractive structures are also possible. The number of interchangeable reflection surface sections may be in the range between two and one hundred, for example in the range between two and twenty.

Arrangements of the interchangeable reflection surface sections in accordance with certain embodiments were found to be particularly suitable for obtaining a meaningful test result.

An interchangeable reflection surface section according to a further embodiment facilitates a test of appropriate diffraction grating structures. Examples of such diffraction grating structures are described in DE 10 2019 200 698 A1.

An interchangeable reflection surface section according to another embodiment actually contributes to the object field exposure during the production operation of the EUV projection exposure apparatus. A degradation of a reflectivity or of any other optical behavior of the interchangeable reflection surface section, which potentially deviates from the remainder of the EUV collector, can then be determined using highly precise monitoring instruments for monitoring illumination parameters of the object field, which are regularly provided with the projection exposure apparatus in any case.

An embodiment of an interchangeable reflection surface section for realizing an interchange illumination region ensures that effects of a degradation of the interchangeable reflection surface section do not have an undesirably pronounced effect on a performance of the projection exposure apparatus during operation. The aspect ratio x/y of longitudinal side dimension to narrow side dimension of the respective facet reflection surface may be greater than five, may be greater than eight and may also be greater than ten.

A jump within the meaning of this claim is present if an integral over the area of the interchange illumination region generated by the considered interchangeable reflection surface section integrated over the narrow side dimension has a non-negligible profile section that extends perpendicular to the longitudinal side dimension of the field facets.

The facet reflection surfaces can be designed so that an intensity contribution of the respective field facet to the illumination of an object field depending on the longitudinal side dimension of the field facet has a comparatively small resultant gradient.

A design of the at least one interchangeable reflection surface section according to a further embodiment ensures that a degradation of the interchangeable reflection surface section does not have an effect on the object field illumination during the production operation of the projection exposure apparatus. The interchange illumination region is then situated in what is known as an overexposed area, that is to say a section of the far field not used by a facet allocation of the field facets. Such a far field section not used by a facet allocation of the field facets may be located outside of an entire field facet arrangement region, or else between the field facets, for example where there is between field facet groups for structural reasons a free area in the far field arrangement plane not occupied by field facets.

An interchange apparatus according to another embodiment facilitates an exchange, in particular an automated exchange, between interchangeable reflection surface sections. The interchange apparatus may comprise a cartridge having a plurality of swap interchangeable reflection surface sections. The gripper device and the transfer arm of the interchange apparatus may also serve to transfer the swap interchangeable reflection surface section from an interchangeable reflection surface section store or cartridge to the collector recess and to insert the swap interchangeable reflection surface section into the assigned holder, in particular once again while overcoming the locking effect so that a completely automated interchange process is possible with the aid of the interchange apparatus.

A vacuum lock according to yet another embodiment facilitates an interchange of an interchangeable reflection surface section without needing to vent a vacuum chamber of the projection exposure apparatus, in which the EUV collector is housed, to atmospheric pressure.

The advantages of an associated illumination system, of an associated optical system, of an associated projection exposure apparatus, of an associated production method, and of an associated microstructured or nanostructured component correspond to those which have already been explained above with reference to the collector according to the invention.

In particular, a semiconductor component, for example a memory chip, can be produced using the projection exposure apparatus.

### BRIEF DESCRIPTION OF THE DRAWINGS

Exemplary embodiments of the invention are explained in greater detail below with reference to the drawing, in which:

FIG. 1 schematically shows a projection exposure apparatus for EUV microlithography;

FIG. 2 shows details of a light source of the projection exposure apparatus in the surroundings of an EUV collector for guiding EUV used light from a plasma source region to a field facet mirror of an illumination optical unit of the projection exposure apparatus, with the EUV collector being illustrated schematically in a meridional section;

FIG. 3 shows a plan view of the EUV collector with a direction of view on the reflection surface, with positions of interchangeable reflection surface sections of the EUV collector being highlighted in each case;

FIG. 4 shows a section as per line A-A in FIG. 3, with two of the interchangeable reflection sections highlighted in FIG. 3 once again being indicated and being depicted with a very exaggerated curvature in comparison with the reflection surface surroundings of the collector reflection surface;

FIG. 5 shows an enlarged detail for illustrating exactly one interchangeable reflection surface section;

FIG. 6 shows a plan view of a field facet mirror of the projection exposure apparatus in a far field arrangement plane, with an interchange illumination region of the far field mirror, which is illuminated by way of exactly one interchangeable reflection surface section of the EUV collector, being highlighted;

FIG. 7 shows, in an illustration similar to FIG. 6, the field facet mirror with further examples of interchange illumination regions which are fully illuminated by way of corresponding interchangeable reflection surface sections and which are arranged firstly at the location of field facets of the field facet mirror and secondly at the location of a far field in the far field arrangement plane not used by a facet movement;

FIG. 8 shows a round interchange illumination region in the far field arrangement plane;

FIG. 9 shows an illumination intensity signal, integrated over a vertical coordinate y according to FIG. 8, in the far field arrangement plane, plotted against a horizontal coordinate x in FIG. 8 and normalized to a value of 1;

FIG. 10 shows, in an illustration similar to FIG. 8, a further, elliptical, horizontally orientated interchange illumination region in the far field arrangement plane;

FIG. 11 once again shows, in an illustration similar to FIG. 9, the integrated and normalized intensity signal of the interchange illumination region according to FIG. 10;

FIG. 12 shows, in an illustration similar to FIG. 8, a further, elliptical, vertically orientated interchangeable illumination region in the far field arrangement plane;

FIG. 13 once again shows, in an illustration similar to FIG. 9, the integrated and normalized intensity signal of the interchange illumination region according to FIG. 12;

FIG. 14 shows, in an illustration similar to FIG. 8, a further, square interchange illumination region in the far field arrangement plane;

FIG. 15 once again shows, in an illustration similar to FIG. 9, the integrated and normalized intensity signal of the interchange illumination region according to FIG. 14;

FIG. 16 shows, in an illustration similar to FIG. 8, a further, parallelogram-shaped interchangeable illumination region in the far field arrangement plane;

FIG. 17 once again shows, in an illustration similar to FIG. 9, the integrated and normalized intensity signal of the interchange illumination region according to FIG. 16; and

FIG. 18 schematically shows an interchange apparatus for exchanging an interchangeable reflection surface section held on the EUV collector according to FIG. 3 with a swap interchangeable reflection surface section.

### DETAILED DESCRIPTION

A microlithographic projection exposure apparatus 1 comprises a light source 2 for illumination light or imaging light 3, which will be explained in yet more detail below. The light source 2 is an EUV light source, which produces light in a wavelength range of, for example, between 5 nm and 30 nm, in particular between 5 nm and 15 nm. The illumination light or imaging light 3 is also referred to as EUV used light below.

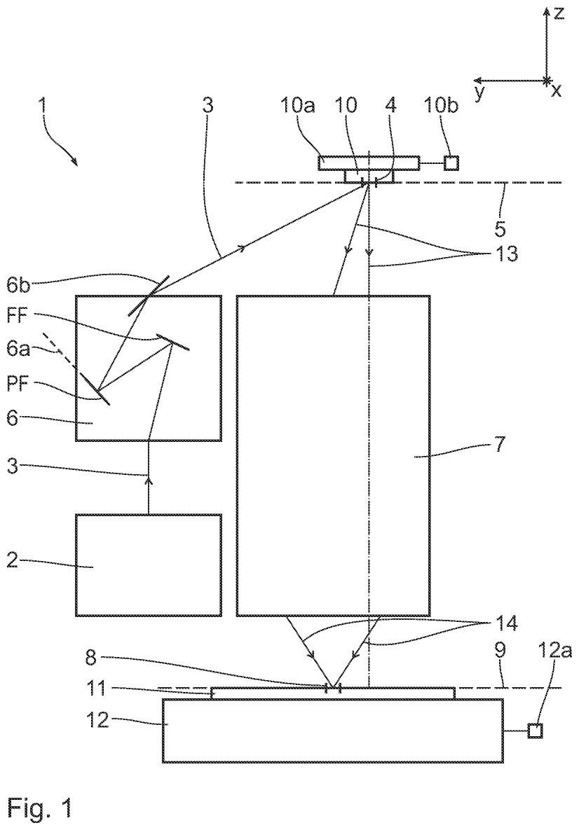

In particular, the light source 2 can be a light source with a wavelength of 13.5 nm or a light source with a wavelength of 6.9 nm. Other EUV wavelengths are also possible. A beam path of the illumination light 3 is depicted very schematically in FIG. 1.

An illumination optical unit 6 is used to guide the illumination light 3 from the light source 2 to an object field 4 in an object plane 5. Said illumination optical unit comprises a field facet mirror FF illustrated highly schematically in FIG. 1 and a pupil facet mirror PF disposed downstream in the beam path of the illumination light 3 and likewise illustrated highly schematically. A field-forming mirror 6b for grazing incidence (GI mirror; grazing incidence mirror) is arranged in the beam path of the illumination light 3 between the pupil facet mirror PF, which is arranged in a pupil plane 6a of the illumination optical unit, and the object field 4. Such a GI mirror 6b is not mandatory.

Pupil facets (not illustrated in any more detail) of the pupil facet mirror PF are part of a transfer optical unit, which transfer, and in particular image, field facets (likewise not illustrated) of the field facet mirror FF into the object field 4 in a manner being superimposed on one another. An embodiment known from the prior art can be used for the field facet mirror FF on the one hand and the pupil facet mirror PF on the other hand. By way of example, such an illumination optical unit is known from DE 10 2009 045 096 A1.

Using a projection optical unit or imaging optical unit 7, the object field 4 is imaged into an image field 8 in an image plane 9 with a predefined reduction scale. Projection optical units which can be used for this purpose are known from e.g. DE 10 2012 202 675 A1.

In order to facilitate the description of the projection exposure apparatus 1 and individual optical components, a Cartesian xyz-coordinate system is indicated in the drawing, from which system the respective positional relationship of the components illustrated in the figures is evident. In FIG. 1, the x-direction runs perpendicular to the plane of the drawing into the latter. The y-direction runs toward the left in FIG. 1 and the z-direction runs upward in FIG. 1. The object plane 5 runs parallel to the xy-plane. The x-axes of the various coordinate systems in the drawing run parallel to one another and the y- and z-axes are tilted about the respective x-axis such that the respective xy-plane spans an arrangement plane of the optical component.

The object field 4 and the image field 8 are rectangular. Alternatively, it is also possible for the object field 4 and the image field 8 to have a bent or curved embodiment, that is to say, in particular, a partial ring shape. The object field 4 and the image field 8 have an x/y-aspect ratio of greater than 1. Therefore, the object field 4 has a longer object field dimension in the x-direction and a shorter object field dimension in the y-direction. These object field dimensions extend along the field coordinates x and y.

One of the exemplary embodiments known from the prior art can be used for the projection optical unit 7. What is imaged in this case is a portion of a reflection mask 10, also referred to as reticle, coinciding with the object field 4. The reticle 10 is carried by a reticle holder 10a. The reticle holder 10a is displaced by a reticle displacement drive 10b.

The imaging by way of the projection optical unit 7 is implemented on the surface of a substrate 11 in the form of a wafer, which is carried by a substrate holder 12. The substrate holder 12 is displaced by a wafer or substrate displacement drive 12a.

FIG. 1 schematically depicts, between the reticle 10 and the projection optical unit 7, a beam 13 of the illumination light 3 that enters into said projection optical unit and, between the projection optical unit 7 and the substrate 11, a beam 14 of the illumination light 3 that emerges from the projection optical unit 7. An image field-side numerical aperture (NA) of the projection optical unit 7 is not reproduced to scale in FIG. 1.

The projection exposure apparatus 1 is of the scanner type. Both the reticle 10 and the substrate 11 are scanned in the y-direction during the operation of the projection exposure apparatus 1. A stepper type of the projection exposure apparatus 1, in which a stepwise displacement of the reticle 10 and of the substrate 11 in the y-direction is effected between individual exposures of the substrate 11, is also possible. These displacements are effected synchronously with one another by an appropriate actuation of the displacement drives 10b and 12a.

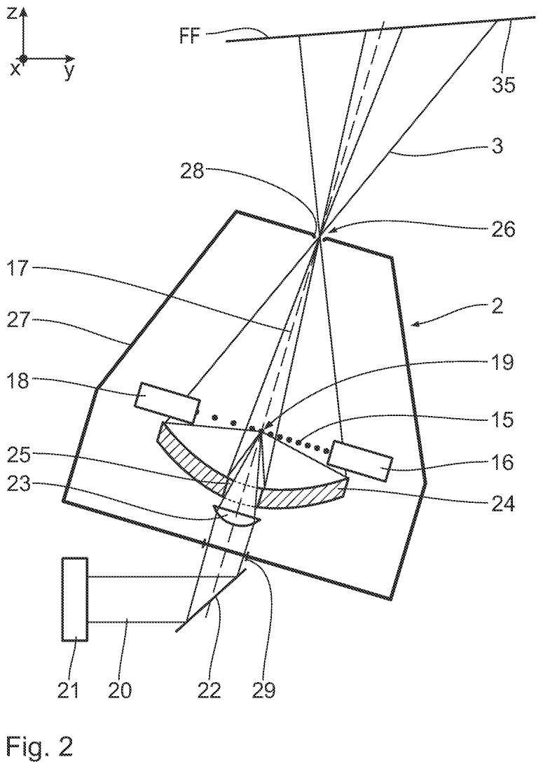

FIG. 2 shows details of the light source 2.

The light source 2 is an LPP (laser produced plasma) source. For the purposes of producing plasma, tin droplets 15 are produced as a continuous droplet sequence by a tin droplet generator 16. A trajectory of the tin droplets 15 runs transversely to a principal ray direction 17 of the EUV used light 3. Here, the tin droplets 15 drop freely between the tin droplet generator 16 and a tin capturing device 18, with said droplets passing through a plasma source region 19. The EUV used light 3 is emitted by the plasma source region 19. When the tin droplet 15 arrives in the plasma source region 19, pump light 20 from a pump light source 21 impinges on said tin droplet. The pump light source 21 can be an infrared laser source in the form of, e.g., a CO₂ laser. A different IR laser source is also possible, in particular a solid-state laser, for example an Nd:YAG laser.

The pump light 20 is transferred into the plasma source region 19 by way of a mirror 22, which can be a mirror that is tiltable in a controlled fashion, and by way of a focusing lens element 23. A plasma emitting the EUV used light 3 is produced by the pump light impingement from the tin droplet 15 arriving in the plasma source region 19. A beam path of the EUV used light 3 is illustrated in FIG. 2 between the plasma source region 19 and the field facet mirror FF, to the extent that the EUV used light is reflected by a collector mirror 24, which is also referred to as EUV collector 24 below. The EUV collector 24 comprises a central passage opening 25 for the pump light 20 focused toward the plasma source region 19 by way of the focusing lens element 23. The collector 24 is embodied as an ellipsoid mirror and transfers the EUV used light 3 emitted by the plasma source region 19, which is arranged at one ellipsoid focus, to an intermediate focus 26 of the EUV used light 3, which is arranged at the other ellipsoid focus of the collector 24.

The field facet mirror FF is arranged downstream of the intermediate focus 26 in the beam path of the EUV used light 3, in the region of a far field of the EUV used light 3.

The EUV collector 24 and further components of the light source 2, which may be the tin droplet generator 16, the tin capturing device 18 and the focusing lens element 23, are arranged in a vacuum housing 27. The vacuum housing 27 has a passage opening 28 in the region of the intermediate focus 26. In the region of an entrance of the pump light 20 into the vacuum housing 27, the latter comprises a pump light entrance window 29.

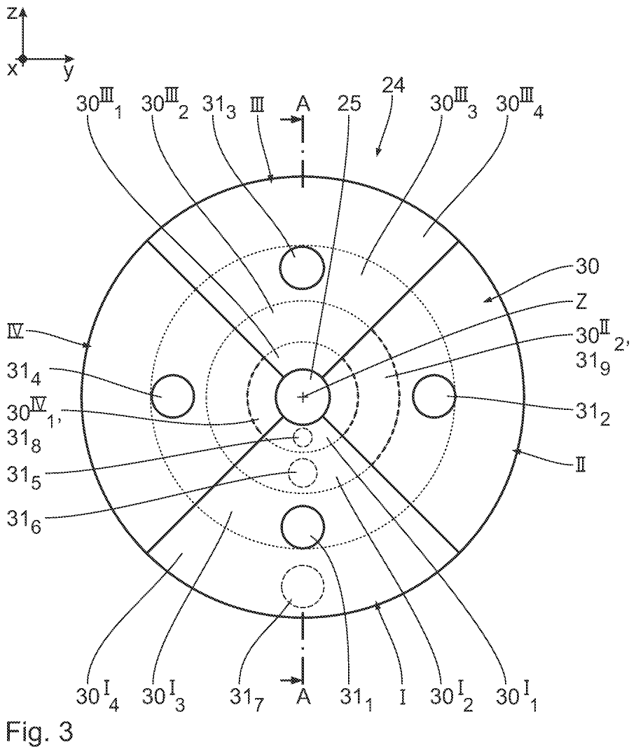

FIG. 3 shows the EUV collector 24 in a plan view, less schematically in comparison with the illustration of FIG. 2. The EUV collector 24 has a reflection surface 30, which faces the observer in the plan view according to FIG. 3. The reflection surface 30 has a coating that is reflective and, in particular, highly reflective for the EUV used light 3. This coating can be embodied as a many layer or multi-layer coating.

The reflection surface 30 is curved in order to attain a specified optical power. Depending on the exemplary embodiment, the reflection surface 30 can be ellipsoidally curved, with a first ellipsoid focus being able to lie at the location of the source region 19 and a second ellipsoid focus being able to lie at the location of the intermediate focus 26. Other curvatures of the reflection surface 30 for attaining a respective specified optical power are also possible, for example a spherical, parabolic or hyperboloid curvature. The reflection surface 30 can also be subdivided into various, mutually separated reflection surface regions. In particular, the collector 24 can be designed as what is known as a nested collector with a plurality of collector shells, which each in turn may have a reflection surface that is curved in order to obtain a specified optical power. By way of example, the collector 24 may have various mutually separate collector subunits, which may have different curvature designs of their reflection surface. By way of example, a collector subunit may have a spherically curved reflection surface and at least one further collector subunit may have a curved surface in the form of an ellipsoid and/or hyperboloid and/or paraboloid. Examples of such collector designs are found in U.S. Pat. No. 9,754,695 B2 and the references cited therein.

The EUV collector 24 has at least one interchangeable reflection section 31. Arrangement variants of the at least one interchangeable reflection surface section 31 of the EUV collector 24 are each provided with a subscript index i in FIG. 3. The collector 24 may have one or more such interchangeable reflection sections 31ᵢ. The number of interchangeable reflection surface sections can lie in the range between one and 50, for example. The EUV collector 24 regularly has a plurality of interchangeable reflection surface sections 31ᵢ.

In the embodiment depicted using solid lines, the collector 24 has four interchangeable reflection surface sections 31₁ to 31₄, which are arranged in equally distributed fashion in four quadrants of the reflection surface 30 in the circumferential direction. The interchangeable reflection surface sections 31₁ to 31₄ are arranged at the same distance from a center Z of the reflection surface 30 that is bounded in circular fashion in the illustrated exemplary embodiment. In the case of a reflection surface 30 with a different bounding or edge contour, the center Z may also be defined as area centroid of the respective edge contour of the reflection surface 30 or of a reflection surface region.

Further exemplary arrangements and embodiments of interchangeable reflection surface sections 31ᵢ are provided with further index numbers in FIG. 3 and depicted using dashed lines. As seen from the center Z, the interchangeable reflection surface sections 31₅, 31₆, 31₇ are arranged at the same circumferential position as the interchangeable reflection surface section 31₁, albeit at different distances from the center Z. In this case, the interchangeable reflection surface section 31s is closest to the center Z. The interchangeable reflection surface section 31₆ is located radially between the interchangeable reflection surface section 31₅ and the interchangeable reflection surface section 31₁. Radially, the interchangeable reflection surface section 31₇ is further away from the center Z than the interchangeable reflection surface section 31₁.

Schematically, FIG. 3 indicates a subdivision of the entire reflection surface 30 firstly into four quadrants I to IV and then a further subdivision of these quadrants I to IV into circumferential sections 30^{I}ᵢ (i=1 to 4) to 30^{IV}ᵢ (i=1 to 4) with the index running radially from the inside to the outside. Thus, in total there are 16 such reflection surface subsections 30^{I . . . IV}ᵢ. The circumferential sections 30^{IV}₁ and 30^{II}₂ are highlighted, using dashed lines, as further examples of interchangeable reflection surface sections 31₈ and 31₉. In this case, the entire circumferential sections 30^{IV}₁ and 30^{II}₂ are used as the interchangeable reflection surfaces 31₈ and 31₉.

The interchangeable reflection surface sections 31ᵢ may have a circular edge but they may also have edges in the style of the circumferential sections 30^{I to IV}ᵢ or else have other edge shapes, for example an elliptical, square, rectangular, regular polygonal, for example hexagonal, or else irregular edge.

The interchangeable reflection surface sections 31ᵢ may have different reflection surface sizes. Such a size of the reflection surface of the respective interchangeable reflection surface section 31 may be less than 1% of the entire reflection surface 30 of the collector 24. A greater proportion of the area is also possible, for example up to 1%, up to 2%, up to 3%, up to 5%, up to 10% or optionally even a greater proportion of the area.

The interchangeable reflection surface sections 31 may cover a few percent of the entire reflection surface 30. Alternatively, a greater proportion of the reflection surface 30 may also be occupied by interchangeable reflection surface sections 31, for example up to 10% or else up to 25%, up to 50%, up to 75% or even up to 100% of the entire reflection surface 30. Thus, collectively, even the entire reflection surface 30 may be constructed from interchangeable reflection surface sections 31ᵢ. In this case, a plurality of interchangeable reflection surface sections 31ᵢ are regularly available.

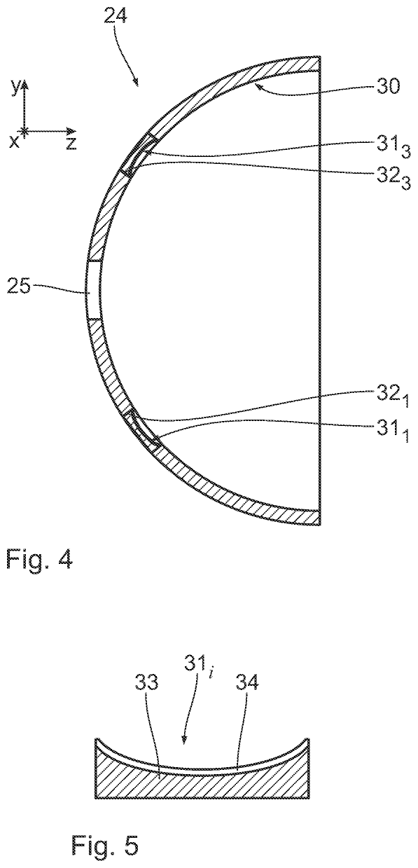

FIG. 4 shows a section through the collector 24 and through the two interchangeable reflection surface sections 31₁, 31₃. A curvature of these interchangeable reflection surface sections 31₁, 31₃ has been depicted in very exaggerated fashion in FIG. 4. In fact, the interchangeable reflection surface sections 31ᵢ are curved in accordance with the specified optical power of the EUV collector 24.

Each interchangeable reflection surface section 31ᵢ is held in a respective collector recess 32ᵢ, complementary thereto, of the EUV collector 24.

The interchangeable reflection surface sections 31ᵢ each merge seamlessly into reflection surface surroundings which extend adjacently to the respective interchangeable reflection surface sections 31ᵢ.

The interchangeable reflection surface sections 31ᵢ have a highly reflective coating for the illumination light 3, which is also referred to as EUV used light. A highly reflective coating can be constructed from a plurality of a bi-layers, for example as a periodic or virtually periodic sequence of molybdenum and silicon layers. Alternatively or in addition, ruthenium or metal oxides, metal nitrides or metal borides can be used as coating material. The reflection surface 30 of the EUV collector 24 carries a corresponding reflective coating, optionally for a greater EUV wavelength bandwidth, beyond the interchangeable reflection surface sections 31ᵢ.

As an alternative or in addition to a highly reflective coating, the interchangeable reflection surface sections 31ᵢ may carry a diffraction grating for diffracting the EUV used light 3 and/or for diffracting light components at other wavelengths. Alternatively or in addition, the interchangeable reflection surface section 31 may be designed as a computer-generated hologram (CGH), at least in regions.

A holder, not depicted in any more detail in FIG. 4, serves to hold the respective interchangeable reflection surface section 31ᵢ in the assigned collector recess 32ᵢ.

The interchangeable reflection surface sections 31ᵢ facilitate a service-life test for certain materials of a substrate body 33 (cf. FIG. 5) of the interchangeable reflection surface section 31ᵢ and/or of a coating 34 of the substrate body 33, that is to say, for example, of a highly reflective coating and/or of a coating designed as a diffraction grating.

A main body of the EUV collector 24 and/or the substrate body 33 of the respective interchangeable reflection surface section 31 can be manufactured from aluminum. Alternative materials for this substrate body are copper, alloys comprising the constituent copper and/or aluminum or alloys, produced by powder metallurgy, of copper and aluminum oxide or different structural forms of silicon.

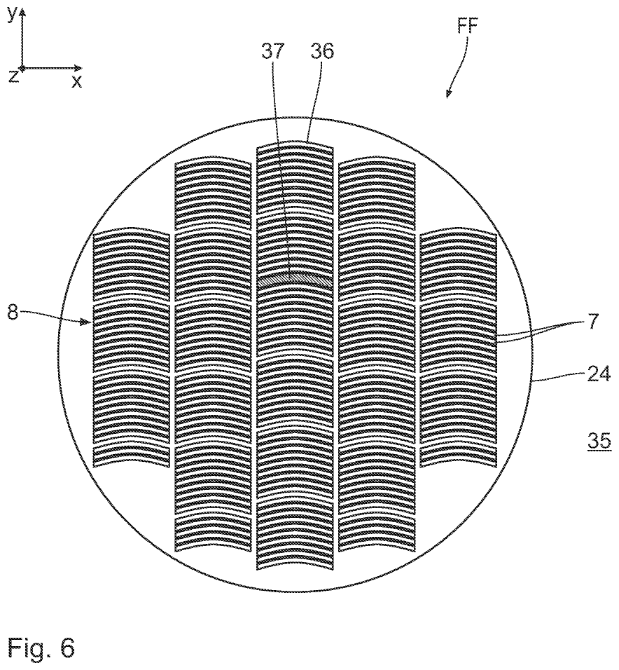

FIG. 6 shows an arrangement of an embodiment of a field facet mirror FF of the illumination optical unit 6 in a far field arrangement plane 35 of the illumination optical unit 6, that is to say in a far field of the EUV collector 24. The field facet mirror FF comprises a plurality of field facets 36 which have a curved embodiment in the embodiment according to FIG. 6 and which may also have a rectangular design in alternative embodiments of the field facet mirror FF. As is known as a matter of principle from the prior art, the field facets 36 are each imaged into the object field 4 by components of the illumination optical unit 6. The field facets 36 comprise facet reflection surfaces with an x/y-aspect ratio of a longitudinal side dimension x to a narrow side dimension y which is greater than three and which may be of the order of ten, for example.

The respective interchangeable reflection surface section 31ᵢ of the EUV collector 24 is designed such that an interchange illumination region 37 is illuminated in the far field arrangement plane 35 of the field facet mirror FF via the interchangeable reflection surface section 31ᵢ. The illumination light 3 emanating from the source region 19 is therefore reflected by the respective interchangeable reflection surface section 31ᵢ to an interchange illumination region 37ᵢ in the far field arrangement plane 35.

In the case of the arrangement of the interchange illumination region 37 according to FIG. 6, the latter has approximately the contour and the extent of exactly one of the field facets 36.

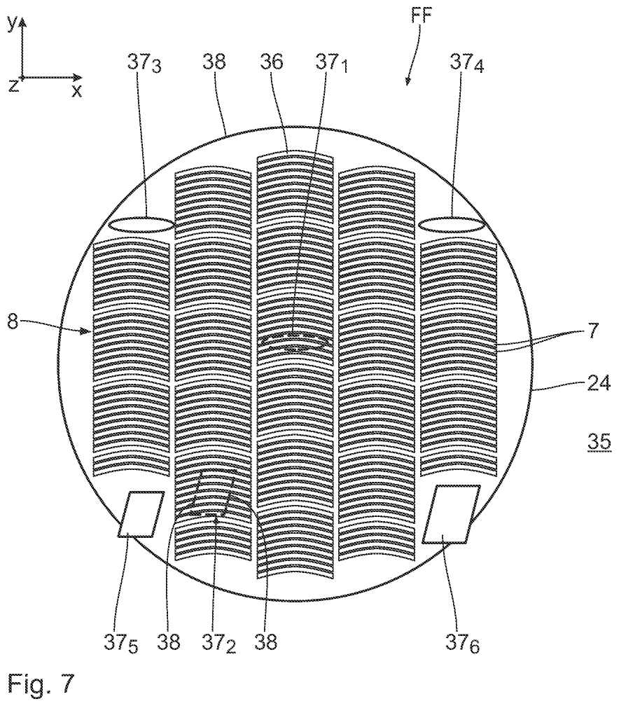

FIG. 7 shows further arrangement variants of interchange illumination regions 37ᵢ.

One of these of variants of the interchange illumination regions 37₁ is designed as an ellipse with an x/y-aspect ratio possibly ranging between two and 15, for example, that is to say as the ellipse lying in FIG. 7. The interchange illumination region 37₁ may cover a plurality of field facets 36 in the y-dimension. In the x-dimension, the interchange illumination region 37₁ may also cover a plurality of field facets 36 or, as illustrated in FIG. 7, exactly one field facet 36.

The further interchange illumination region 37₂ depicted in FIG. 7 has a parallelogram-shaped edge contour. In the x-dimension, the interchange illumination region 37 extends over less than one x-extent of the field facets 36. In the y-dimension, the interchange illumination region 37₂ extends over a plurality of field facets 36. An angle between oblique contour sections 38 of the parallelogram of the interchange illumination region 37₂ may adopt an absolute value ranging between 15° and 75°, in particular ranging between 30° and 60°, and in particular of the order of 45°, in relation to the x-axis.

Further variants of interchange illumination regions 37₃, 37₄, 37₅ and 37₆ are arranged in the far field arrangement plane 35 outside of an occupancy by the field facets 36, that is to say outside of a field facet arrangement region. The interchange illumination regions 37₃ff may be arranged completely within a used far field, the edges of which are indicated at 38 in FIGS. 6 and 7. Alternatively, the interchange illumination regions 37ᵢ may in any case also be partly located outside of the used far field 38 in the far field arrangement plane 35, as indicated in variants 37₅ and 37₆.

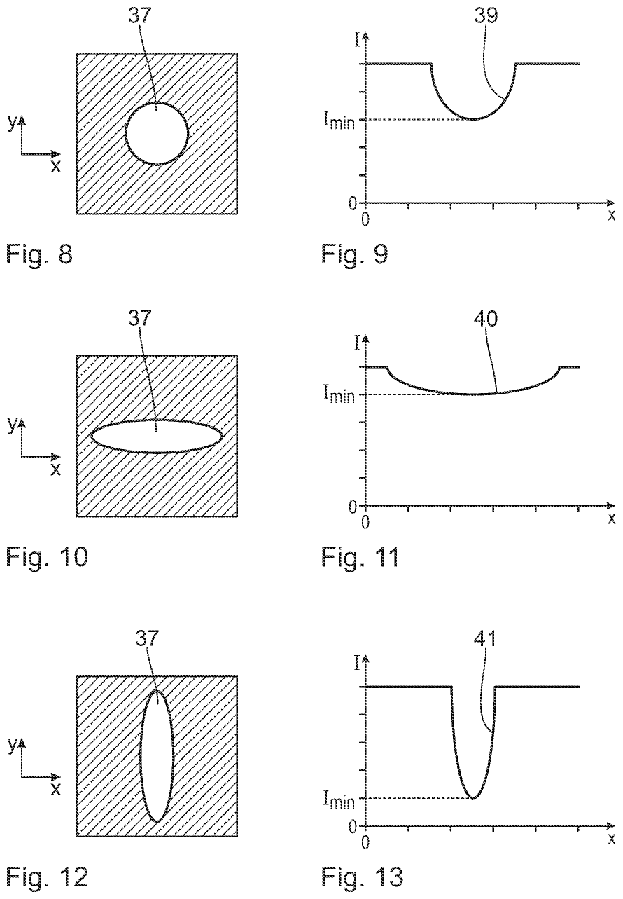

The arrangement and the shaping of edge contours of the interchangeable reflection sections 31ᵢ is such that a reflectivity degradation of the assigned interchange illumination regions 37ᵢ has the smallest possible effects on a productivity of the projection exposure apparatus 1 during the production of microstructured or nanostructured components. To this end, a scan-integrated influence on a homogeneity or uniformity of an illumination intensity over the object field 4 is considered in particular, which will be explained below using the FIGS. 8 to 17 on the basis of selected examples of edge contours of the interchange illumination regions 37ᵢ. For illustrative purposes, the assumption is made here in each case that a reflectivity of the interchangeable reflection surface section 31 is zero and that of the reflection surface surroundings of the reflection surface 30 around this interchangeable reflection surface section is one. In reality, the difference between the reflectivity of the interchangeable reflection surface section 31 and the reflectivity of the reflection surface surroundings of the reflection surface 30 around this interchangeable reflection surface section 31 is regularly smaller.

FIG. 8 shows an interchange illumination region 37 with a circular edge contour in exemplary fashion.

FIG. 9 shows a scan-integrated effect of an edge contour according to FIG. 8 on a scan-integrated (scan direction: y-direction) illumination intensity of illumination or imaging light 3, which is guided over a far field region in which the interchange illumination region 37 according to FIG. 8 is situated. In this case, the illumination light 31 is considered, which is guided to the object field 4 firstly from the interchange illumination region 37 according to FIG. 8 and secondly from the surroundings around this interchange illumination region 37. The circular form of the edge contour leads to a dip 39 in the scan-integrated intensity I as a function of the x-coordinate of the object field 4.

An intensity minimum Iₘᵢₙ is at approximately 60% of the scan-integrated intensity at x-coordinates outside of the interchange illumination region 37, the scan-integrated intensity having been normalized to one.

FIGS. 10 and 11 show the conditions in the case of an interchange illumination region 37 with an edge contour in the form of a lying ellipse in the style of the interchange illumination region 37₁ according to FIG. 7. In comparison with FIG. 9, the scan-integrated intensity curve according to FIG. 11 has an intensity dip 40 of a substantially smaller relative amplitude.

In FIG. 11, the intensity minimum Iₘᵢₙ is at approximately 80% of the normalized intensity I.

FIGS. 12 and 13 show the conditions in the case of an interchange illumination region 37 in the form of a “standing ellipse”. In comparison with FIG. 10, the edge contour has thus been rotated through 90° such that an x/y-ratio is significantly less than one.

The intensity effect in the case of the scan integration is correspondingly dramatic, depicted in FIG. 13 with a very steep dip 41 and a minimum intensity Iₘᵢₙ of the order of 20% of the normalized intensity.

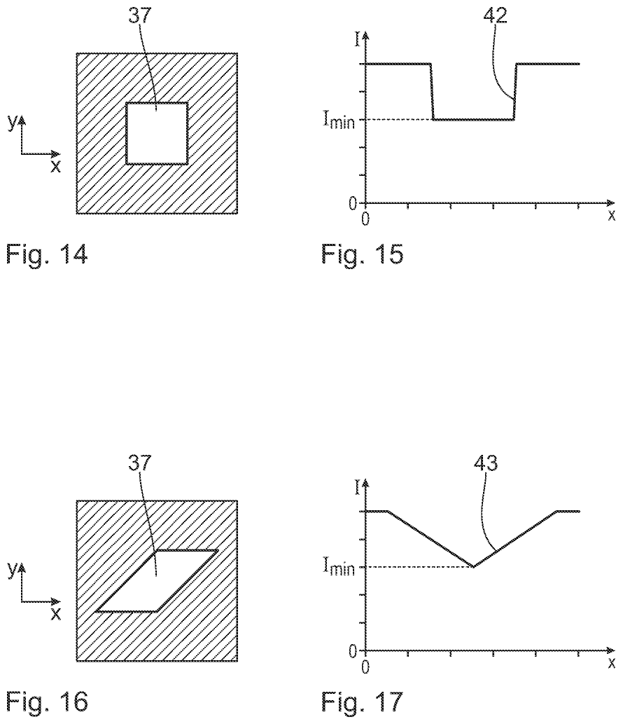

FIGS. 14 and 15 show the conditions in the case of an interchange illumination region 37 in the form of a square with side surfaces parallel to the x- or y-coordinate. On account of this orientation there is a scan-integrated intensity curve according to FIG. 15, with jumps that correspond to the smallest and largest x-coordinates of the interchange illumination region 37 according to FIG. 14. A minimum intensity Iₘᵢₙ of a corresponding rectangular dip 42 of the scan-integrated intensity curve according to FIG. 15 arises at approximately 60% of the normalized intensity I.

FIGS. 16 and 17 show the conditions in the case of an interchange illumination region 37 with a parallelogram-shaped edge contour corresponding to the interchange illumination regions 37₅, 37₆ according to FIG. 7.

The parallelogram shape causes a dip 43 of the scan-integrated intensity without a jump and with a minimum intensity Iₘᵢₙ of the order of 60% of the normalized intensity.

Since an x-dependence of these interchangeable reflection surface sections 31 either is moderate as a matter of principle and/or contains no jump, the edge contours of the interchange illumination regions 37 according to FIGS. 10 and 16 are preferred. This shape of the interchange illumination regions 37 according to FIGS. 10 and 16 then yields, based on the specified optical power 24, the respective shape of the interchangeable reflection surface section 31. In the simplest case, the edge contour of the respective interchangeable reflection surface section 31 is imaged with a given linear magnification into the far field arrangement plane 35 such that the edge contours of the interchange illumination regions according to FIGS. 8, 10, 12, 14 and 16 lead to corresponding edge contours of the interchangeable reflection surface sections 31. Thus, the interchange illumination regions 37ᵢ could be a scale projection of the assigned interchangeable reflection surface sections 31ᵢ.

In particular the shape of the interchange illumination regions 37 according to FIGS. 10 and 16 yields a small resultant gradient in relation to the I(x)-dependence, that is to say a gradient of the I(x)-dependence, which is less than the gradient of the corresponding I(x)-dependencies of the interchangeable reflection surface sections 31 which lead to the interchange illumination regions 37 according to FIGS. 8, 12 and 14.

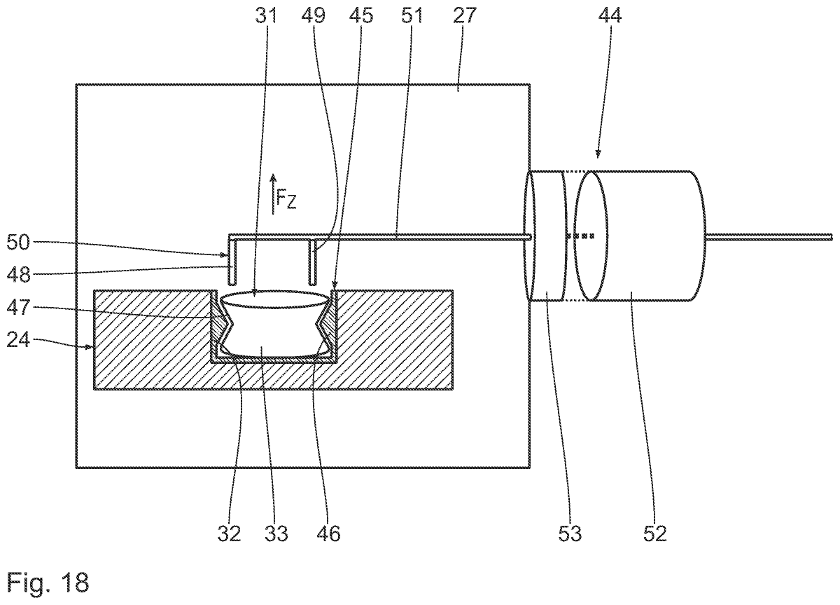

FIG. 18 schematically shows an interchange apparatus 44 for exchanging an interchangeable reflection surface section 31 held at the EUV collector 24 with a similar swap interchangeable reflection surface section not depicted here.

FIG. 18 moreover depicts an example of a holder 45 of the EUV collector 24 for the interchangeable reflection surface section 31 for holding the latter in the collector recess 32. This holder 45 has a circumferential detent collar 46, which is inserted in the collector recess 32 and which engages in a circumferential groove 47, complementary thereto, of the substrate body 33 of the interchangeable reflection surface section 31. As a result of the interaction of the detent collar 46 of the holder 45 with the circumferential groove 47 of the interchangeable reflection surface section 31 there is a latching hold of the interchangeable reflection surface section 31 in the collector recess 32. This latching holding force can be overcome by exerting a corresponding pulling force F_{Z} in the direction perpendicular to the reflection surface of the interchangeable reflection surface section 31.

The interchange apparatus 44 comprises a gripper device 50, illustrated schematically by two suction/gripper arms 48, 49, for grasping the interchangeable reflection surface section 31 and for overcoming a locking effect of the holder 45 by exerting the pulling force F_{Z}. Furthermore, the interchange apparatus 44 comprises a transfer arm 51 which is mechanically connected to the gripper device 50. The transfer arm 51 serves to transfer the grasped interchangeable reflection surface section 31 from the collector recess 32 to an external transfer location, at which a cartridge 52 for a plurality of corresponding interchangeable reflection surface sections 31ᵢ may be located.

The interchange apparatus 44 can be designed such that at least one of the interchangeable reflection surface sections 31 is exchanged during operating pauses of the projection exposure apparatus and, in particular, of the light source 2, during which there is no vacuum in the vacuum chamber or vacuum housing 27. In an alternative embodiment, which is shown schematically in FIG. 18, this interchange can also be carried out when there is a vacuum or negative pressure in the vacuum chamber 27. In the present case, the interchange apparatus 44 comprises a vacuum lock 53 between the vacuum chamber 52 in which the EUV collector 24 is arranged and the external transfer location.

In order to produce a microstructured or nanostructured component, the projection exposure apparatus 1 is used as follows: First, the reflection mask 10 or the reticle and the substrate or the wafer 11 are provided. Subsequently, a structure on the reticle 10 is projected onto a light-sensitive layer of the wafer 11 with the aid of the projection exposure apparatus 1. Then, a microstructure or nanostructure on the wafer 11, and hence the microstructured component, is produced by developing the light-sensitive layer.

What is claimed is:

1. An extreme-ultraviolet (EUV) collector for an EUV projection exposure apparatus and configured to guide EUV used light emanating from a source region of an EUV light source, comprising:
at least one reflection surface that is curved to obtain a specified optical power,
a plurality of interchangeable reflection surface sections, and
a plurality of holders assigned to and configured to hold the interchangeable reflection surface sections in collector recesses which are configured complementary to the interchangeable reflection surface sections and are located in the EUV collector,
wherein the interchangeable reflection surface sections are curved in accordance with the specified optical power.

2. The EUV collector as claimed in claim 1, wherein the interchangeable reflection surface sections number between 2 and 100.

3. The EUV collector as claimed in claim 1, wherein the reflection surface of the EUV collector has a surface center, and the interchangeable reflection surface sections are arranged at different distances from the surface center.

4. The EUV collector as claimed in claim 1, wherein the reflection surface of the EUV collector has a surface center, and the interchangeable reflection surface sections are arranged in different circumferential regions around the surface center.

5. The EUV collector as claimed in claim 1, wherein the interchangeable reflection surface sections support one or more diffraction gratings.

6. An apparatus comprising:
an EUV collector as claimed in claim 1, and
an EUV projection exposure apparatus having a field facet mirror with a plurality of field facets, wherein each of the field facets is configured to image the EUV used light into an object field of the EUV projection exposure apparatus via components of an illumination optical unit, a reticle arranged in the object field, wherein the interchangeable reflection surface sections are configured such that interchange illumination regions of the field facet mirror are fully illuminated in a far field arrangement plane of the field facet mirror via corresponding ones of the interchangeable reflection surface sections.

7. The EUV collector as claimed in claim 6, wherein the field facets have facet reflection surfaces having an aspect ratio x/y of a longitudinal side dimension x to a narrow side dimension y which is greater than 3, and wherein an area of a given one of the interchange illumination regions depends on the longitudinal side dimension x integrated over the narrow side dimension y, having no jumps.

8. An apparatus comprising:
an EUV collector as claimed in claim 1, and
an EUV projection exposure apparatus having a field facet mirror with a plurality of field facets, wherein each of the field facets is configured to image the EUV used light into an object field of the EUV projection exposure apparatus via components of an illumination optical unit, a reticle arranged in the object field, wherein the interchangeable reflection surface sections are configured such that interchange illumination regions are fully illuminated in a far field arrangement plane of the field facet mirror via corresponding ones of the interchangeable reflection surface sections which are adjacent to an arrangement region of the field facets of the field facet mirror.

9. An interchange apparatus for exchanging given ones of the interchangeable reflection surface sections held on an EUV collector as claimed in claim 1 with given swap interchangeable reflection surface sections, comprising:
a gripper device configured to grasp the given interchangeable reflection surface sections and to overcome a locking effect of corresponding given ones of the holders of the EUV collector for the given interchangeable reflection surface sections,
a transfer arm which is mechanically connected to the gripper device and is configured to transfer grasped ones of the interchangeable reflection surface sections from corresponding ones of the collector recesses to an external transfer location.

10. The interchange apparatus as claimed in claim 9, further comprising a vacuum lock between a vacuum chamber housing the EUV collector and the external transfer location.

11. An illumination system comprising:
an EUV collector as claimed in claim 1, and
an illumination optical unit for illuminating an object field, to illuminate an object arranged in the object field with the EUV used light as illumination light.

12. An optical system comprising:
an illumination system as claimed in claim 11, and
a projection optical unit for imaging the object field into an image field, to expose a substrate arranged in the image field with at least a section of the object arranged in the object field.

13. A projection exposure apparatus comprising an optical system as claimed in claim 12 and an EUV light source.

14. A method for producing a structured component comprising:
providing a reticle and a wafer,
projecting an image of a structure provided on the reticle onto a light-sensitive layer of the wafer with the projection exposure apparatus as claimed in claim 13,
producing a microstructure and/or nanostructure on the wafer.
